(19) United States
(12) Patent Application Publication
(10) Pub. No.: US 2007/0131276 A1
(43) Pub. Date: Jun. 14, 2007

(54) Photo-voltaic cells including solar cells incorporating silver-alloy reflective and/or transparent conductive surfaces

(76) Inventor: Han Nee, Newport Coast, CA (US)

Correspondence Address: Woodard, Emhardt, Moriarty, McNett & Henry LLP;Bank One Center/Tower, Suite 3700, 111 Monument Circle, Indianapolis, IN, 46204-5137, US

(21) Appl. No.: 10/759,795

(22) Filed: Jan. 16, 2004

Related U.S. Application Data
(60) Provisional application No. 60/440,602, filed on Jan. 16, 2003.

(51) Int. Cl. H01L 31/00

(52) U.S. Cl. 136/256

(57) ABSTRACT

The current invention provides for the manufacture of solar voltaic cells with high sunlight to electricity conversion efficiencies by using improved silver-alloy thin films with a thickness in the range of 30 to 60 as a back reflector/conductor. The back reflector surface may be smooth or roughened depending on the design of the solar voltaic cell and the reflective surface used. Silver-alloy thin film in the thickness range of 3 to 10 nanometers can be used to replace traditional transparent conductor such as indium oxide, indium tin oxide, zinc oxide, tin oxide etc. Elements that can be alloyed with silver to create alloys for use in the invention include, Pd, Cr, Zr, Pt, Au, Cu, Cd, B, In, Zn, Mg, Be, Ni, Ti, Si, Li, Al, Mn, Mo, W, Ga, Ge, Sn, and Sb. These alloys may be present in the silver-alloys in amounts ranging from 0.01 to 10.0 a/o percent. Preferably, elements such as of Cu, In, Zn, Mg, Ni, Ti, Si Al, Mn, Pd, Pt, and Sn are alloyed with silver, these elements are present in the alloy the amounts ranging from 0.05 to 5 a/o percent.

This application claims priority to U.S. Provisional Patent Application Ser. No. 60/440,602, filed on Jan. 16, 2003, which is incorporated by reference herein.

### FIELD OF THE INVENTION

This invention relates generally to the use of silver-alloys in the construction of photo-voltaic cells including but not limited to solar voltaic cells.

### BACKGROUND OF THE INVENTION

As the world's supply of fossil fuels being depleted to satisfy the energy needs of an ever increasing human population, there is an increasing need to utilize renewable sources of energy such as solar, wind, and tidal power. Environmental damage associated with the use of fossil fuels such as global warming and the risks inherent in the use of nuclear energy such as the potential proliferation of nuclear weapons have made renewable energy sources such as solar power all the more attractive. Sunlight as a source of electricity is renewable, clean, and virtually ubiquitous. Unfortunately, the initial cost of building devices to generate electricity from solar power is still too high to compete against more conventional sources of electrical generation such as the burning of coal, oil, and natural gas.

Finding ways to lower the cost of generating electricity from photo-voltaic cells has been the subject of intense research and development for the past 2 or 3 decades. But even with the best available technology, the cost of generating electricity from sunlight is still higher than the cost of generating electricity using more conventional methods such as burning fossil fuels. A typical photo-voltaic cells comprises a p-n junction manufactured from semiconductor materials. Light impinging on the p-n junction generates an electromotive force (electrical potential, V).

The most commonly used photo-voltaic cells including solar cells use single crystal (s-Si) silicon, poly-crystal (p-Si) silicon, amorphous (a-Si) silicon or other semiconductor materials as the basis for forming p-n junctions. Light impinging on a p-n junction generates electron-hole pairs separated by the internal electric field of the p-n junction. When a p-n junction is connected to terminals, electrons and holes can be made to flow through external load circuitry. For a more thorough discussion of photo-voltaic cells including solar cells the reader is directed to U.S. Pat. Nos. 4,256,513, 4,608,452, 4,865,999 and 5,023,144, the disclosures of which are hereby incorporated by reference. Very high purity silicon material is necessary for the p-n junction to function effectively. Because silicon is an indirect band gap semiconductor, it must be doped with other compounds to generate minority carriers. Using conventional technology, it is necessary to use a p-n junction (composed largely of high purity silicon) that is on the order of 300 microns thick in order to absorb enough sunlight to generate useful amounts of electricity. The need for such a thick layer of high purity silicon greatly increases the cost of silicon based solar cells.

One approach to lowering the cost of silicon based solar cells is to use light trapping. For a more thorough discussion of light trapping and the design of more efficient solar cells the reader is directed to U.S. Pat. Nos. 4,941,032, 5,486,238, 5,828,117, 5,891,264, 5,986,204, and 6,660,931, the disclosures of which are hereby incorporated by reference. Light trapping is a means of increasing the efficiency of a photo-voltaic cell by using a backside reflective surface to reflect light unabsorbed in the first pass through the p-n junction of the cell back through the p-n junction. Light reflected through the p-n junction generates more electricity from the p-n junction. Taking advantage of this second pass, the p-n junction can be made thinner and therefore the price of manufacturing the photo-voltaic cell lowered.

Generally, low cost aluminum or aluminum alloys are used as the reflective layer. Aluminum surfaces used in such applications reflect about 80 to 85 percent of the light striking them. Any increase in the amount of light reflected back through the p-n junction increases the ratio of light to electricity generated by the cell. Since increased reflectivity is related to an increase in the conversion efficiency of the cell there is a need for a low cost, highly reflective material with good corrosion resistant properties that can be used in the construction of backside reflectors for the manufacture of efficient solar cells.

In conventional photo-voltaic cells, light enters the cell through an electrically conductive layer, which is at least partially transparent to visible light. On the side of a photo-voltaic cell facing the light source, it is necessary to provide a material that is both transparent to light and able to conduct electricity. The transparent property of the material enables light to reach the p-n junction, where electromotive force is generated. While the electrically conductive property of the material enables electrons generated by the p-n junction to flow out of the cell. Conventional transparent conductors include thin layers of gold or metal oxides such as indium oxide, indium tin oxide (ITO), tin oxide, zinc oxide, etc.

Thin films of gold are transparent, corrosion resistant, easy to deposit, conductive, and, unfortunately, expensive. Various metal oxides are transparent; however, they are not very good conductors and often times difficult to apply. To compensate for their low electrical conductivity, transparent conductive layers manufactured from oxides must be made hundreds of nanometers to microns thick in order to create layers that conduct enough electrical current to build useful photo-voltaic cells. Oxide layers are generally applied using a coating process, typically reactive sputtering of a metallic target (e.g. indium tin) or RF sputtering of oxide targets. Both of these coating processes are more expensive process than DC sputtering processes.

Given the expense and manufacturing problems associated with the materials currently used to form transparent conductive, and highly reflective layers in photo-voltaic cells, there is a need for materials for use in the manufacture of photo-voltaic cells, which are inexpensive, corrosion resistant, transparent, efficient electrical conductors, and inexpensive to apply. It is one object of this invention to provide such materials.

### SUMMARY OF THE INVENTION

It is one objective of the current invention to provide a photo-voltaic cell, for example, a solar cell with a high light to electricity conversion efficiency by using an improved silver-alloy thin film, 30 to 60 nanometers in thickness, as a highly reflective back reflector and electrical conductor. The highly reflective back surface may be smooth or roughened depending on the design of the photo-voltaic cell. It is another object of this invention to provide silver-alloys that can be used as transparent electrical conductors in the manufacture of photo-voltaic cells. It is yet another object of this invention to provide silver-alloy thin films, or layers, with a thickness in the range of 3 to 25 nanometers that can be used alone, or in combination with transparent dielectric compounds such as indium oxide, indium tin oxide, tin oxide, zinc oxide, and the like, to form transparent conductive layers. Using silver-alloys of the current invention in the construction of transparent conductive layers allows for the construction of photo-voltaic cells with thinner and less expensive transparent conductive layers. Elements which can be alloyed with silver to produce silver-alloys useful for the practice of this invention include Pd, Cr, Zr, Pt, Au, Cu, Cd, B, In, Zn, Mg, Be, Ni, Ti, Si, Li, Al, Mn, Mo, W, Ga, Ge, Sn, and Sb. These elements may be present in the range of 0.01 to 10.0 a/o percent. Preferably, elements such as Cu, In, Zn, Mg, Ni, Ti, Si, Al, Mn, Pd, Pt, and Sn are alloyed with silver, which are preferably in the range of 0.05 to 5 a/o percent of the alloy, the remainder of alloy is silver.

### BRIEF DESCRIPTION OF THE DRAWINGS

FIG. 1 is a schematic cross sectional view of a photo-voltaic cell, that has a simple p-n junction.

FIG. 2 is a schematic cross-sectional view of a photo-voltaic cell designed such that incident light passes through a transparent substrate before reaching a p-i-n junction.

FIG. 3 is a schematic cross-sectional view of a photo-voltaic cell with a roughened highly reflective back reflective layer and a roughened transparent conductive layer.

### DESCRIPTION OF THE PREFERRED EMBODIMENTS

Specific language is used in the following description and examples to publicly disclose the invention and to convey its principles to others. No limits on the breadth of the patent right based simply on using specific language are intended. Also included are any alteration and modifications to the descriptions that should normally occur to one of ordinary skill in the technology.

As used in this specification the term “atomic percent” or “a/o percent” refers to the ratio of atoms of a particular element or group of elements of the total number of atoms that are identified to be present in a particular alloy. For example, an alloy that is 15 atomic percent element “A” and 85 atomic percent element “B” could be referenced by a formula for that particular alloy: A_{0.15}B_{0.85}.

As used herein the term “of the amount of silver present” is used to describe the amount of a particular additive that is included in the alloy. Used in this fashion, the term means that the amount of silver present, without consideration of the additive, is reduced by the amount of the additive that is present to account for the presence of the additive in a ratio. For example, if the relationship between Ag and an element “X” is A_{0.85}X_{0.15} (respectively 85 a/o percent silver, and 15 a/o percent “X” without considering the amount of the additive that is present in the alloy. And if an additive “B” is present in the alloy at a level 5 atomic percent “of the amount of silver present”: then the relationship between Ag, X, and B is found by subtracting 5 atom percent from the atomic percent of sliver, A_{0.80}X_{0.15} B_{0.05} (respectively 80 a/o percent silver, 15 a/o percent “X”, and 5 a/o percent “B”).

As used in this specification the term “doped semiconductor structure for the conversion of light to electromotive force” refers to structures comprised of materials which interact with light to create electricity. These ‘structures’ are oftentimes used to generate electricity from light, for example sunlight. Electromotive force may be referred as ‘EMF’.

For example, one such “doped semiconductor structure for the conversion of light to electromotive force” is oftentimes referred to as a p-n junction. A p-n junction is comprised of layers of an n-type semiconductor and a p-type semiconductor, wherein the n-type layer and the p-type layers reside next to one another.

Another example of such a “doped semiconductor structure for the conversion of light to electromotive force” is oftentimes referred to as a ‘p-i-n junction’. A p-i-n junction is comprised of a n-type semiconductor layer, an intrinsic semiconductor layer, and a p-type semiconductor, wherein the intrinsic semiconductor layer is located between the p-type and n-type semiconductor layers. Other such semiconductor structure for the conversion of light to electromotive force as are known in the art are also considered to be within the scope of this invention.

N-type semiconductors interact with light to produce areas of negative charges referred to as “electrons”. A typical n-type semiconductor is manufactured by adding compounds such as phosphorus, arsenic, antimony and the like to an intrinsic semiconductor such as silicon. The process of adding elements such as phosphorus, arsenic, antimony to intrinsic semiconductors is oftentimes referred to as “doping”.

P-type semiconductors interact with light to produce “holes”, which carry positive charges. A typical p-type semiconductor is manufactured by adding elements such as boron, aluminum and gallium and the like to an intrinsic semiconductor such as silicon. The process of adding elements such as boron, aluminum and gallium to intrinsic semiconductors is oftentimes referred to as “doping”.

The term “roughened” as used in this specification refers to reflective and/or semi-reflective films, coatings, or layers, which comprise an uneven surface. Roughened surfaces made using the silver-alloys of the present invention may be formed by applying a layer of the silver alloy to a heat resistant surface of the device such as soda-glass, and then heating it to induce grain coarsening and grain boundary grooving within the silver-alloy layer. Roughened surface reflect light from multi-faceted surfaces, thereby scattering light to a greater degree than smooth i. e. un-roughened surfaces. Viewed macroscopically, and under low magnification, roughened surface appear to be more uneven (less smooth or uniform) than surfaces formed by materials with identical, or similar, chemical compositions, which are not roughened.

The term parallel as used in this specification refers to layers or sub-layers comprising planes, or curved surfaces that are always the same distance apart and therefore never meet.

The term substantially parallel refers to layers or a stack of layers which are generally or in essence parallel to one another.

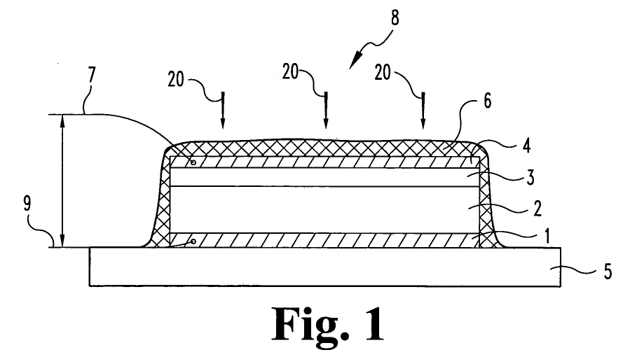

One aspect of the invention is the use of silver-alloys of the present invention in the manufacture of photo-voltaic cells including, for example, solar cells. Referring to FIG. 1, a side view of solar voltaic cell 8, with supporting substrate 5, is comprised, for example, of stainless steel, glass, ceramic, graphite, or the like. Layer 1, which resides parallel to and next to layer 5, is a highly reflective, corrosion resistant, electrical conductor comprising a silver-alloy thin film of the current invention about 30 to 100 nm thick. Layer 2 of solar voltaic cell 8 is a p-type semiconductor.

Layer 3, which is parallel to and resides next to layer 2, is comprised of a n-type semiconductor. Layer 2 and layer 3 comprise doped semiconductor structure for the conversion of light to electromotive force oftentimes referred to as a p-n junction. Layer 4, which is parallel to and resides next to layer 3, is a transparent or (semi-transparent) electrical conductor.

Still referring to FIG. 1, in the embodiment of the invention, the transparent or semi-transparent conductive layer 4 is comprised of a silver-alloy layer, film, or coating of the current invention.

In one embodiment of the invention silver-alloy thin film, or coating of layer 4 is between 3 and 25 nm thick.

In another preferred embodiment of the invention, the silver-alloy thin film or coating of transparent or semi-transparent conductive layer 4 is about 3 to 10 nm thick.

Referring to FIG. 1, typically about 80% to 95% of the incident light passes through protective layer 6, and transparent (or semi-transparent) conductive layer 4 striking the 200 micron thick doped semiconductor structure for the conversion of light to electromotive force (the p-n junction) formed by layers 2 and 3. Light striking the p-n junction generates electrons and holes.

Electrons collect in conductive layer 4, layer 4 is connected to lead wire 7. Holes accumulate in the conductive material of layer 1 connected to lead wire 9. Segregation of the net negative and positive charges from one another creates an electromotive force (EMF) or voltage V). Leads 9 and 7, connected respectively to conductors 1 and 4, transmit the charge generated by voltaic cell 8 to any number of devices.

In a conventional photo-voltaic cell of this type, layer 4 is comprised of a thin (5-15 nm thick) gold layer or a 50 to 300 nm thick dielectric metal-oxide type transparent semiconductor. Obviously the use of gold is inconsistent with the production of a low cost product. Dielectric materials, which are also transparent conductors such as, for example, indium tin indium oxide, indium zinc oxide, indium aluminum oxide, zinc oxide, tin oxide, zinc tin oxide, copper aluminum oxide, cadmium tin oxide, cadmium zinc oxide, cadmium oxide, magnesium indium oxide, cadmium antimony oxide, gallium indium oxide can also be used in layer 4. These oxides are less expensive than gold: however, they are generally less conductive than gold. And due to their low conductivity, transparent conductive layers comprised solely of dielectric transparent metal-oxides must be made thicker than layers of gold layers in order to produce a transparent conductive layer 4 conductive enough to create a useful photo-voltaic cell.

For example, one commonly used metal-oxide used in the manufacture of layer 4 is indium tin oxide. Transparent conductive layers (4) comprised essentially of indium-tin oxide typically is 200 nm or thicker in order to function effectively. Another drawback to the use of metal-oxides to form transparent conductive layers is that these materials are difficult to deposit with relatively inexpensive, DC sputtering processes.

Still referring to FIG. 1, because of their high conductivity, low cost and ease of application copper or aluminum based material are often used to form layer 1. Layer 1 in conventional solar cells is not necessarily highly reflective. However, if layer 1 is made from a highly reflective conductive material such as the silver-alloys of the current invention, the photo-voltaic cell's electricity generating efficiency can be increased.

If the p-n junction is 50% transparent to incident light, then 50% of the incident light will pass through the p-n junction. If layer 1 is not very reflective most of the light passing through the p-n junction is scattered within the cell, and not used to generate electricity. The light to electricity conversion efficiency is improved if layer 1 is reflective. For example, if layer 1 is comprised of a 30 to 60 nm thick aluminum layer 80 to 85% of light in the visible spectrum light striking layer 1 will be reflected back through the p-n junction. A portion of the light reflected through the p-n junction by layer 1 is converted to electrical current thereby increasing the efficiency of the cell.

Certain accelerated aging tests demonstrate that aluminum is corrosion resistant enough to use as the reflective layer in some photo-voltaic cells. Conversely, while a 30 to 100 nm thick layer of pure silver is highly reflective and an excellent electrical conductor, silver corrodes too quickly to be of practical use in the manufacture of most types of photo-voltaic cells. Silver-alloys of the present invention; however, are good electrical conductors, highly reflective, and corrosion resistant that even when these silver based alloys are made into thin films or coatings they are suitable for use in the manufacture of solar cells intended for outdoor use.

The corrosion resistance of photo-voltaic cell 8 can be further improved if the entire cell is encapsulated in an optically transparent coating 6. Coating 6 can be made of material such as, for example, a clear UV cured organic resin.

Elements, which can be alloyed with silver to form silver-alloys compatible with their use in layers 1 or layer 4 of photo-voltaic cell 8 include Pd, Cr, Pt, Zr, Au, Cu, Cd, Zn, Sn, Sb, Ni, Mn, Mg, B, Be, Ge, Ga, Mo, W, Al, In, Si, Ti, Bi, Li. These elements may be present in the silver-alloys in amounts ranging from about 0.01% a/o percent to about 10.0 a/O percent.

In a more preferred embodiment of the current invention, elements that may be alloyed with silver include Al, Cu, Zn, Mn, Mg, Pd, Pt and Ti in amounts ranging from about 0.05% by a/o percent to about 5.0% a/o percent.

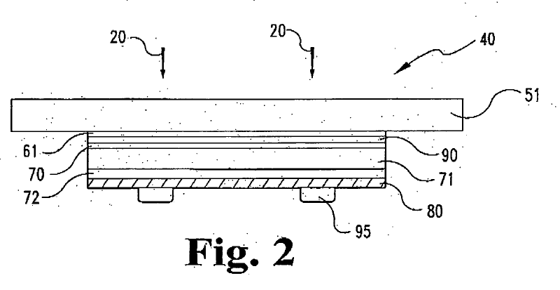

Another embodiment of the current invention is illustrated in FIG. 2. Photo-voltaic cell 40 is comprised of a transparent substrate 51, which may be comprised of materials such as soda-lime glass. In one embodiment of the invention, transparent substrate 51 resides next to a transparent conductive layer, the transparent conductive layer comprises, for example, sub-layers 61 and 90.

As illustrated in FIG. 2 in one embodiment of the invention the transparent conductive layer is comprised of transparent dielectric materials (sub-layers 61 and 90). Transparent dielectric material suitable for the practice of this invention includes, but are not limited to indium oxide, indium tin oxide, indium zinc oxide, indium aluminum oxide, zinc oxide, tin oxide, zinc tin oxide, copper aluminum oxide, cadmium tin oxide, cadmium zinc oxide, cadmium oxide, magnesium indium oxide, cadmium antimony oxide, gallium indium oxide. For example, sub-layer 61 may be comprised of tin oxide and about 300 nm thick.

In another embodiment of the invention, as illustrated with reference to FIG. 2, the transparent conductive layer includes a silver-alloy thin film or coating sub-layer 90 of the current invention and a transparent dielectric material (sub-layer 61).

In still another embodiment of the invention, as illustrated again with reference to FIG. 2, the transparent conductive layer includes a silver-alloy thin film (now designated as sub-layer 61 in FIG. 2) and a transparent dielectric material (now designated as sub-layer 90 in FIG. 2).

Still referring to FIG. 2, transparent conductive layer (sub-layers 61 and 90) resides next to, and is substantially parallel to, amorphous n-type silicon layer 70. N-type semiconductor layer 70 resides next to intrinsically amorphous semiconductor layer 71. Intrinsically amorphous semiconductor layer 71 resides next to amorphous p-type semiconductor layer 72. Taken together layers 70, 71, 72 comprise a doped semiconductor structure for the conversion of light to electromotive force. P-type semiconductor layer 72 resides next to silver-alloy layer 80 of the present invention.

Including layers or coatings of the silver-alloys of the present invention (sub-layers 61 or 90) into transparent conductive layers including transparent dielectric oxides (sub-layers 61 or 90) increases the conductivity of the transparent conductive layer. Therefore, transparent conductive layers that include sub-layers (61 or 90) of silver-alloys of the present can be made to work with thinner sub-layers (61 or 90) of transparent dielectric materials such as indium-tin oxide.

Sub-layers 61 or 90, can be comprised of 3-25 nm thick layers of the silver-alloys of the current invention. These silver-alloy sub-layers (61,90) are substantially parallel to the doped semiconductor structure formed by layer 70, 71, 72 and can be readily deposited using simple DC sputtering. Including sub-layers of silver-alloy into the transparent conductive layer reduces the cost of building photo-electric devices by enabling the device to be constructed with thinner sub-layers (61, 90) of the more expensive to deposit transparent dielectric materials.

Referring to FIG. 2. In one embodiment of the invention silver alloy layer 80, is substantially parallel to, and resides next to, doped semiconductor structure for the conversion of light to electromotive force comprised of layers 70, 71, 72.

Referring again to FIG. 2. In one embodiment of the invention silver-alloy thin film layer or coating 80 is about 50 nm thick.

Still referring to FIG. 2. In another embodiment of the invention silver-alloy film, coating, or layer 80 is greater than 50 nm thick.

Referring to FIG. 2, shown in cross section, is a printed and fire cured silver paste grid screen 90 attached to silver-alloy thin film 80. Light 20 passes through glass substrate 51 to reach the doped semiconductor structure for the conversion of light to electromotive force (p-i-n junction layers 71, 70, 72). Light interacts with the p-i-n junction to generate negatively charged electrons and positively charged holes. Light that passes through the doped semiconductor structure for the conversion of light to electromotive force 70, 71, 72 reaches highly reflective silver-alloy thin film, or layer 80 and is reflected back through layers 70, 71, 72. At least a portion of the light reflected back through the p-i-n junction by highly reflective layer 80 generates negatively charged electrons and positively charged holes. Light reflected by layer 80 through p-i-n junction increase the amount of electricity generated by cell 40 for a given amount of light entering photo-voltaic cell 40.

In one embodiment of the invention reflective layer 80 is combined with grid 90 to form the electrical grid contact on the side of solar voltaic cell 40 furthest from incident light 20.

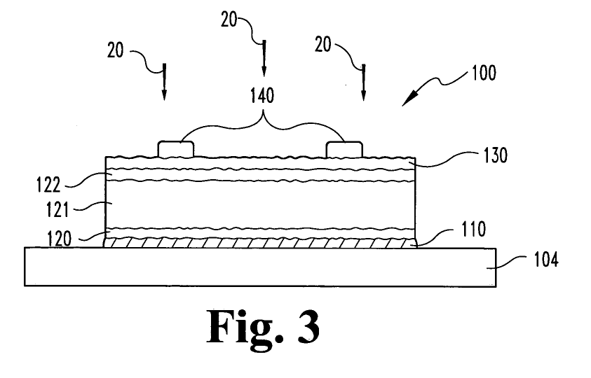

Still another embodiment of the invention is illustrated in FIG. 3. Photo-voltaic cell 100 includes a silver-alloy thin film of the current invention 110 resides next to glass substrate 104. In one embodiment of the invention silver-alloy thin film layer or coating 110 is about 50 nm in thick. Coating 110 can be applied to glass substrate 100 by a DC magnetron sputtering process. Afterwards the silver-alloy coated glass is heat treated at about 450 degrees C. for 20 minutes under a suitable atmosphere.

During the heat treating step, the surface of silver-alloy film 110 is roughened by heat-induced grain coarsening and grain boundary grooving. Roughening of silver-alloy surface 110 promotes light trapping, because roughened (textured) reflective surfaces increase the amount of light reflected back through the other layers comprising photo-voltaic cell 100. Layer 120 resides next to and is substantially parallel to silver-alloy layer 110. Layer 120 also resides next to intrinsic polycrystal silicon layer (i) 121, layer 121 resides next to p-polycrystal silicon layer 122 (p). Taken together layer 120, 121, 122 comprise a p-i-n junction, one type of doped semiconductor structure for the conversion of light to electromotive force. Layer 120, 121, 122 can all be deposited by CVD. In these applications CVD can be carried out at 350 to 400 degrees C. in a mixture of hydrogen, and precursors including, for example, silicon hydride and silicon hydride chloride.

In one embodiment of the invention, the doped semiconductor structure for the conversion of light to electricity (p-i-n junction) formed by sandwiching layer 121 between layers 120 and 122 is coated with transparent conductive layer 130. Transparent conductive layer 130 may be comprised of transparent dielectric compounds such as indium tin oxide, and the like. Indium tin oxide can be applied by reactive ion sputtering from an indium tin sputtering target. Finally, conductor grid 140 (shown in FIG. 3 in cross section) is formed by screen printing and fire curing silver paste.

Light 20 (for example sunlight) shining from the top side of voltaic cell 100 passes through layer 130 to impinge on and interact with p-i-n junction formed by layers 120, 121, 122 to generate negatively charged electrons and positively charged holes. Electrons formed by the p-i-n junction are collected by silver conductor grid 140, while positive charges are collected by back side conductor/reflector 110 forming an electrical circuit. Light passing through the p-i-n junction reaches layer 110 which is substantially parallel to the p-i-n junction and is reflected back through the p-i-n junction. At least a portion of the light reflected back through the p-i-n junction interacts with the junction to generate additional electricity thereby increasing the overall conversion efficiency of photo-voltaic cell 100

In another embodiment of the invention silver-alloy thin films, or layers, of the current invention can be used in the construction of any photo-voltaic cells including, but not limited to, photo-voltaic cells which have the capacity to convert sunlight, or light generated by lasers, diodes, liquid crystal displays, incandescent or fluorescent sources, etc.

### EXAMPLES

All examples are non-limiting and are merely representative or illustrative of the various aspects, features, and embodiments of the present invention.

### Example 1

Referring now to FIG. 1 for illustrative purposes. A photo-voltaic cell, similar to device 8, is constructed in order to test the stability of a silver-alloy of the present invention in the manufacture of weather resistant solar cells. Beginning with substrate 5, which may be comprised of materials such as stainless steel, successive layers substantially parallel to one another as illustrated in FIG. 1 are laid down.

Layer 1, which resides next to layer 5, is about 50 nm thick and comprised of a silver-alloy including, for example, aluminum 0.6 a/o percent, copper 1.0 a/o percent and silver 98.4 a/o percent. Layer 2 resides next to silver-alloy thin film or coating layer 1. Layer 2 is 50 nm thick and comprised of p-type semiconductor material comprised of, for example, silicon doped with, for example, at least one of the following compounds boron, aluminum, gallium, or the like.

Layer 3 resides next to layer 2. Layer 3 is a n-type semiconductor about 50 nm thick comprised of, for example, silicon doped with, for example, at least one of the following compounds antimony, arsenic, phosphorous, or the like. Layers 2 and layer 3 taken together form a p-n junction, one type of doped semiconductor structure for the conversion of light to electromotive force. Layer 4 resides next to layer 3 of the p-n junction. Layer 4 is a silver-alloy thin film of the present invention substantially parallel to the plane of the doped semiconductor structure. Layer 4 is about 6 nm thick and is comprised of, for example, palladium 1.0 wt. %, copper 1.0 wt. % and silver 98.0 wt. %. Solar voltaic cell 8 can be encapsulated with a clear, water resistant materials such as a UV curable organic compound.

The stability of solar voltaic cell 8 is tested in an accelerated aging test to determine if device 8 is suitable for outdoor use. Solar voltaic cell 8, is held for 10 days at 80 degrees C., 85% Relative Humidity (RH). The performance of solar voltaic 8 is measured both before and after the accelerated aging test and no significant degradation of the cell's performance is observed.

### Example 2

Referring now to FIG. 3 for illustrative purposes. A photo-voltaic cell, similar to device 100, is constructed in order to test the stability of a silver-alloy of the present invention in the manufacture of weather resistant solar cells. A silver-alloy thin film, coating, or layer 110, about 50 nm thick, is deposited on layer 104 using, a DC sputtering process and a silver-alloy target. The silver-alloy target used to deposit layer 110 comprises 3.0 a/o percent zinc, 1.0 percent copper and 96.0 a/o percent silver.

The average reflectivity, in the visible spectrum, of silver-alloy thin film 110 is about 95%. The reflectivity of the silver-alloy layer is higher than the reflectivity of the commonly used aluminum based materials, which have reflectivity values the range of 80 to 83%. Solar voltaic cells 100 manufactured with silver-alloy thin films 110 have higher light to electricity conversion efficiencies than solar voltaic cells manufactured with aluminum alloys.

Silver-alloy layer 110 is substantially parallel to doped semiconductor structure for the conversion of light to electromotive force comprised of layers 120, 121, 122.

The stability of solar voltaic cell 100 is tested in an accelerated aging test to determine if device 8 is suitable for outdoor use. Solar voltaic cell 100, is held for 10 days at 80 degrees C., 85% Relative Humidity (RH). The performance of solar voltaic 100 is measured both before and after the accelerated aging test and no degradation of the cell's performance is observed.

Silver alloys of the current invention of have good conductivity, corrosion resistance even when the are used in layers only 3 to 25 nm thick. These silver-alloys are also easily applied by a DC sputtering process, thus they are useful for the manufacture of photo-voltaic cells especially for cells intended for outdoor use such as solar-voltaic cells. In some embodiments silver-alloy thin films of the present invention are at least semi-transparent to light, for example, to light in the visible region of the spectrum.

Unless specifically identified to the contrary, all terms used herein are used to include their normal and customary terminology. Further, while various embodiments of photo-voltaic devices having specific components and uses, and methods of manufacture have been illustrated herein, it is to be understood that any selected embodiment can include one or more of the specific components and/or steps described for another embodiment where possible.

Further, any theory of operation, proof, or finding stated herein is meant to further enhance understanding of the present invention and is not intended to make the scope of the present invention dependent upon such theory, proof, or finding.

While the invention has been illustrated and described in detail in the drawings and foregoing description, the same is to be considered as illustrative and not restrictive in character, it being understood that only the preferred embodiments have been shown and described and that all changes and modifications that come within the spirit of the invention are desired to be protected. And while the invention was illustrated using specific examples, and theoretical arguments, accounts, and illustrations, these illustrations and the accompanying discussion should by no means be interpreted as limiting the invention.

1-8. (canceled)

9. A photo-voltaic device for the conversion of light to electricity, comprising:
a doped semiconductor structure for the conversion of light to electromotive force residing in a first plane; and
a silver-alloy layer residing in a second plane, said silver alloy including silver and magnesium, wherein the relationship between the amounts of silver and magnesium in the silver-alloy is defined by AgₓMgₚ, wherein 0.9<x<0.9999, and 0.0001<p<0.10, and wherein said first plane is substantially parallel to said second plane.

10. The photo-voltaic device of claim 9, wherein 0.0005<p<0.05.

11. The photo-voltaic device of claim 9, wherein said silver-alloy layer is 3 to 25 nm thick.

12. The photo-voltaic device of claim 9, wherein said silver-alloy layer surface is roughened.

13-32. (canceled)
